(19) United States
(12) Patent Application Publication
(10) Pub. No.: US 2004/0060660 A1
(43) Pub. Date: Apr. 1, 2004

(54) Control of plasma density with broadband RF sensor

(75) Inventors: Pete I. Klimecky, Portland, OR (US); Fred L. Terry JR., Ann Arbor, MI (US); Jessy W. Grizzle, Ann Arbor, MI (US); Craig Garvin, Arlington, MA (US)

Correspondence Address: David B. Ritchie, Thelen Reid & Priest LLP, P. O. Box 640640, San Jose, CA, 95164-0640, US

(73) Assignee: Lam Research Inc., a Delaware Corporation

(21) Appl. No.: 10/672,475

(22) Filed: Sep. 25, 2003

Related U.S. Application Data
(60) Provisional application No. 60/414,463, filed on Sep. 26, 2002.

(51) Int. Cl. H01L 21/306

(52) U.S. Cl. 156/345.28; 156/345.44

(57) ABSTRACT

A plasma processing system has a chamber, a workpiece holder in an interior of the chamber, a first power circuit, a second power circuit, and a feedback circuit. The first power circuit has a first power supply coupled to a first matching network. The first matching network is coupled to a coil adjacent to the chamber. The second power circuit has a second power supply coupled to a second matching network. The second matching network is coupled to the workpiece holder. The feedback circuit includes a radio frequency (RF) probe and a controller. The RF probe is partially disposed in an interior of the chamber. The controller is coupled to the RF probe and the first power circuit. The RF probe measures a change in plasma density in the interior of the chamber and the controller adjusts the first power supply in response to the change in plasma density.

### CROSS-REFERENCE TO RELATED APPLICATIONS

The present application claims the benefit of U.S. Provisional Patent Application Serial No. 60/414,463, filed Sep. 26, 2003 entitled “The Control of Plasma Density With the Broadband RF sensor” in the name of inventors Pete I. Klimecky, Fred L. Terry Jr., Jessy W. Grizzle, Craig Garvin, and commonly assigned herewith.

### STATEMENT REGARDING FEDERALLY SPONSORED RESEARCH OR DEVELOPMENT

This invention was made with United States Government support under Cooperative Agreement 70NANB8H4067 awarded by the National Institute of Standards and Technology (NIST). The United States Government has certain rights in the invention.

### FIELD OF THE INVENTION

The present invention relates to plasma processing of semiconductor devices. More particularly, the present invention relates to control of plasma density in a plasma processing system.

### BACKGROUND OF THE INVENTION

Various forms of processing with ionized gases, such as plasma etching and reactive ion etching, are increasing in importance particularly in the area of semiconductor device manufacturing. Of particular interest are the devices used in the etching process. FIG. 1 illustrates a conventional inductively coupled plasma etching system 100 that may be used in the processing and fabrication of semiconductor devices. Inductively coupled plasma processing system 100 includes a plasma reactor 102 having a plasma chamber 104 therein. A transformer coupled power (TCP) controller 106 and a bias power controller 108 respectively control a TCP power supply 110 and a bias power supply 112 influencing the plasma created within plasma chamber 104.

TCP power controller 106 sets a set point for TCP power supply 110 configured to supply a radio frequency (RF) signal, tuned by a TCP match network 114, to a TCP coil 116 located near plasma chamber 104. A RF transparent window 118 is typically provided to separate TCP coil 116 from plasma chamber 104 while allowing energy to pass from TCP coil 116 to plasma chamber 104.

Bias power controller 108 sets a set point for bias power supply 112 configured to supply a RF signal, tuned by a bias match network 120, to an electrode 122 located within the plasma reactor 104 creating a direct current (DC) bias above electrode 122 which is adapted to receive a substrate 124, such as a semi-conductor wafer, being processed.

A gas supply mechanism 126, such as a pendulum control valve, typically supplies the proper chemistry required for the manufacturing process to the interior of plasma reactor 104. A gas exhaust mechanism 128 removes particles from within plasma chamber 104 and maintains a particular pressure within plasma chamber 104. A pressure controller 130 controls both gas supply mechanism 126 and gas exhaust mechanism 128. A temperature controller 134 controls the temperature of plasma chamber 104 to a selected temperature setpoint using heaters 136, such as heating cartridges, around plasma chamber 104.

In plasma chamber 104, substrate etching is achieved by exposing substrate 104 to ionized gas compounds (plasma) under vacuum. The etching process starts when the gases are conveyed into plasma chamber 104. The RF power delivered by TCP coil 116 and tuned by TCP match network 110 ionizes the gases. The RF power, delivered by electrode 122 and tuned by bias match network 120, induces a DC bias on substrate 124 to control the direction and energy of ion bombardment of substrate 124. During the etching process, the plasma reacts chemically with the surface of substrate 124 to remove material not covered by a photoresistive mask.

Input parameters such as plasma reactor settings are of fundamental importance in plasma processing. The amount of actual TCP power, bias power, gas pressure, gas temperature, and gas flow within plasma chamber 104 greatly affects the process conditions. Significant variance in actual power delivered to plasma chamber 104 may unexpectedly change the anticipated value of other process variable parameters such as neutral and ionized particle density, temperature, and etch rate.

Therefore, a need exists for a system, method, and apparatus for more effectively controlling the plasma density in a plasma processing system. A primary purpose of the present invention is to solve these needs and provide further, related advantages.

### BRIEF DESCRIPTION OF THE INVENTION

A plasma processing system has a chamber, a workpiece holder in an interior of the chamber, a first power circuit, a second power circuit, and a feedback circuit. The first power circuit has a first power supply coupled to a first matching network. The first matching network is coupled to a coil adjacent to the chamber. The second power circuit has a second power supply coupled to a second matching network. The second matching network is coupled to the workpiece holder. The feedback circuit includes a radio frequency (RF) probe and a controller. The RF probe is partially disposed in an interior of the chamber. The controller is coupled to the RF probe and the first power circuit. The RF probe measures a change in plasma density in the interior of the chamber and the controller adjusts the first power supply in response to the change in plasma density.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a diagram schematically illustrating a plasma etching system in accordance with a prior art.

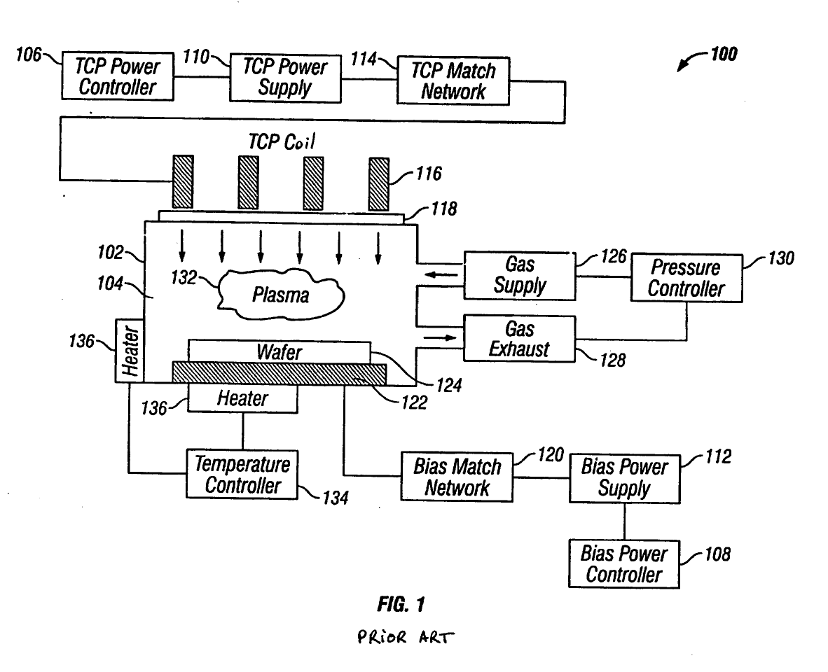

FIG. 2 is a diagram schematically illustrating a plasma etching system in accordance with one embodiment of the present invention.

FIG. 3 is a flow diagram illustrating a method for controlling a plasma density in a plasma etching system in accordance with one embodiment of the present invention.

FIG. 4 is a graph illustrating measured reflection coefficient over a spectrum of frequencies in accordance with one embodiment of the present invention.

### DETAILED DESCRIPTION

Embodiments of the present invention are described herein in the context of a control of plasma density with a broadband RF sensor. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

In accordance with one embodiment of the present invention, the components, process steps, and/or data structures may be implemented using various types of operating systems (OS), computing platforms, firmware, computer programs, computer languages, and/or general-purpose machines. The method can be run as a programmed process running on processing circuitry. The processing circuitry can take the form of numerous combinations of processors and operating systems, or a stand-alone device. The process can be implemented as instructions executed by such hardware, hardware alone, or any combination thereof. The software may be stored on a program storage device readable by a machine.

In addition, those of ordinary skill in the art will recognize that devices of a less general purpose nature, such as hardwired devices, field programmable logic devices (FPLDs), including field programmable gate arrays (FPGAs) and complex programmable logic devices (CPLDs), application specific integrated circuits (ASICs), or the like, may also be used without departing from the scope and spirit of the inventive concepts disclosed herein.

In accordance with one embodiment of the present invention, the method may be implemented on a data processing computer such as a personal computer, workstation computer, mainframe computer, or high performance server running an OS such as Solaris® available from Sun Microsystems, Inc. of Palo Alto, Calif., Microsoft® Windows® XP and Windows® 2000, available form Microsoft Corporation of Redmond, Wash., or various versions of the Unix operating system such as Linux available from a number of vendors. The method may also be implemented on a multiple-processor system, or in a computing environment including various peripherals such as input devices, output devices, displays, pointing devices, memories, storage devices, media interfaces for transferring data to and from the processor(s), and the like. In addition, such a computer system or computing environment may be networked locally, or over the Internet.

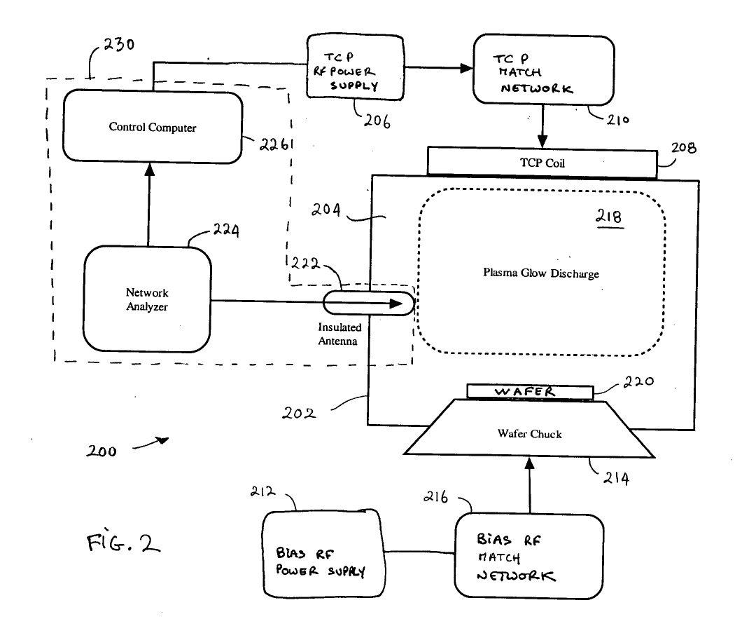

Real-time plasma density is directly correlated with real-time etch variations. Thus, the real-time monitoring of plasma density enables real-time control of the etch variations on a wafer being processed in a plasma etching system. The real-time monitoring of plasma density in the chamber may be achieved with a broadband RF probe partially disposed in an interior of the plasma chamber. FIG. 2 illustrates a plasma etching system 200 with real-time feedback control of plasma density in accordance with one embodiment of the present invention.

The plasma processing system 200 includes a plasma reactor 202 having a plasma chamber 204 therein. A TCP power supply 206 supplies RF power to a TCP coil 208 via a TCP match network 210. A bias power supply 212 supplies RF power to a workpiece support, such as a wafer chuck 214, via a bias match network 216. Both TCP power supply 206 and bias power supply 212 influence the plasma 218 created within plasma chamber 204.

The TCP power supply 206 is configured to supply RF energy to the TCP coil 208 so to create plasma 218 provided ionizable gases are supplied to plasma chamber 204. A RF transparent window (not shown) is typically provided to separate TCP coil 208 from plasma chamber 204 while allowing energy to pass from TCP coil 208 to plasma chamber 204.

Bias power supply 212 is configured to supply a RF signal, tuned by the bias match network 216, to the wafer chuck 214 creating a direct current (DC) bias above wafer chuck 214 which is adapted to receive a substrate such as a wafer 220, being processed.

A feedback circuit 230 is coupled to the TCP power supply 206. The feedback circuit includes a probe 222, a network analyzer 224, and a control computer 226. The probe 222 is partially disposed in the interior of the chamber 204. The probe 204 may be a broadband RF probe, more particularly, a broadband RF peak resonance absorption sensor. The probe 222 comprises a small microwave antenna inserted about 3″ into the sidewall of the chamber 204 and is surrounded by a protective quartz sheath (not shown). The probe may also be placed about 4″ from the bottom of the chamber 204. The location of the probe 222 with respect to the chamber 204 is specified here for illustration purposes only. The probe 222 is electrically coupled to the network analyzer 224.

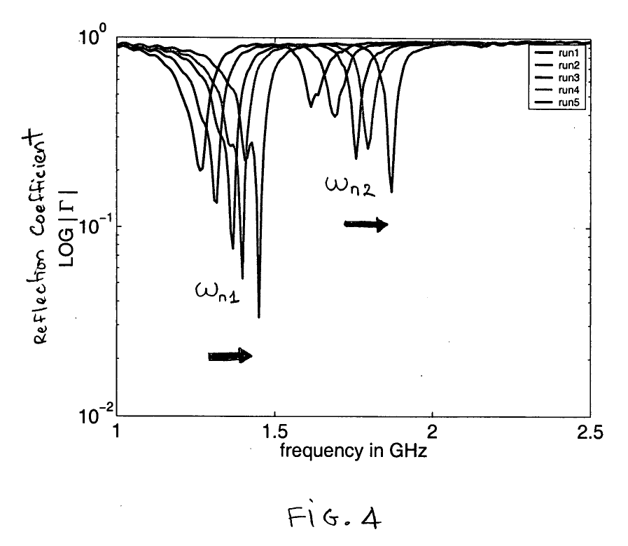

The network analyzer 224 supplies microwave signals with low power (mW) to the probe 222. The microwave signals are then launched into the chamber cavity 204 sweeping the plasma 218 inside the chamber 204. The reflection coefficient is then measured over a broad spectrum of frequencies, for example between 500 Mhz and 3 GHz. An example of a graph illustrating the measured real-time data is illustrated in FIG. 4 and is described in more detail below. The network analyzer 224 sends the real-time data to the control computer 226. Those of ordinary skill in the art will appreciate that the network analyzer shown here is not intended to be limiting and that other devices that measures the magnitude of the reflected microwave signal can be used without departing from the inventive concepts herein disclosed.

The control computer 226 receives the real-time data and analyzes any changes in the reflection coefficients measured over the broadband spectrum. The computer then adjusts the TCP power supply 206 in response to the analysis of the real-time measured data to affect and control the plasma density in the interior of the chamber 204.

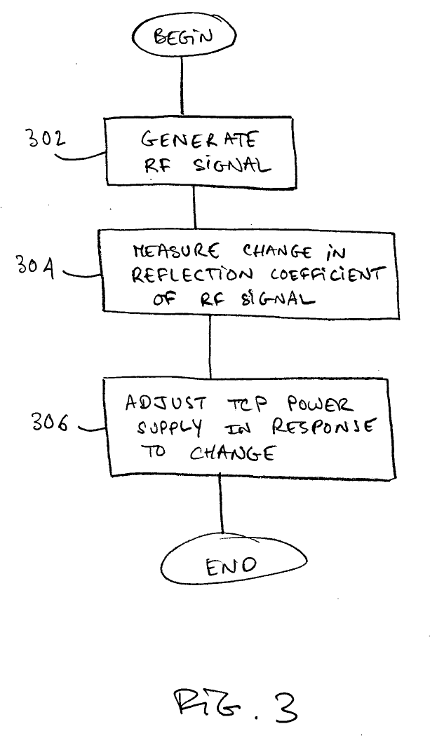

FIG. 3 is a flow diagram illustrates a method for controlling plasma density in the plasma etching system of FIG. 2. At 302, the network analyzer 224 supplies RF signals to the probe 222 inside the chamber 204 over a broad spectrum of frequencies, for example 500 Mhz to 3 Ghz. At 304, the network analyzer 224 measures the reflection coefficient over the broad spectrum of frequencies as illustrated in FIG. 4.

The reflection coefficient of the absorbed microwave power has specific resonance frequencies dependent upon the chamber geometry and the permitivity of the medium (plasma density, wafer surface chemistry, chamber wall state, delivered plasma power). FIG. 4 shows two prominent resonance modes, labeled ωn1 and ωn2 from several runs (run 1 through run 5). It is known that these resonance frequencies shift in the presence of plasma, because the plasma density influences the medium permitivity. In particular, it has been shown that shifts to higher frequencies indicate higher electron density, and shifts to lower frequencies indicate lower electron density. The increase in plasma density is represented by the arrows pointing to the right. FIG. 4 illustrates the two prominent peak frequencies respectively shifting to the right after each successive run. Although several plasma factors influence the overall shape of the reflection coefficient signal, only the plasma frequency is responsible for the peak resonance position. Thus, changes in broadband peak frequencies are attributed to changes in plasma density. The network analyzer 224 sends the real-time reflection coefficient measured over the broad spectrum of frequencies to the control computer 226.

At 306, the control computer 226 adjusts the TCP power supply 206 in response to the changes in broadband peak frequencies. Thus, for example, the control computer compensates for a loss in the plasma density of plasma 218 by increasing the TCP RF power supplied to the TCP coil 208, thereby quickly leveling the etch rate variations of the wafer 220.

Etch variations in a plasma etching process correlates with plasma density changes. The presently claimed invention allows a real-time monitoring of any changes in plasma density using the RF broadband probe 222 with the implementation of a real-time feedback controller that corrects for plasma density changes by adjusting TCP power in response to the real-time monitoring of changes in plasma density. The presently disclosed technique can be used to both increase throughput and reduce variations in etch processes.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims.

What is claimed is:

1. An apparatus for controlling the plasma density in a plasma processing system having a workpiece holder within a chamber, the apparatus comprising:
a power circuit arranged to supply RF power to the chamber suitable for striking a plasma within the chamber; and
a feedback circuit coupled to said power circuit, said feedback circuit including a RF probe partially disposed in an interior of the chamber, said RF probe measuring a change in plasma density, said feedback circuit adjusting RF power in response to said change in plasma density.

2. The apparatus of claim 1 wherein said power circuit includes a power supply coupled to a matching network, said matching network coupled to a coil adjacent to the chamber.

3. The apparatus of claim 1 wherein said feedback circuit further comprises:
a network analyzer coupled to said RF probe;
a computer coupled to said network analyzer,
wherein said network analyzer measures a plurality of reflection coefficients of the RF power generated by said RF probe over a spectrum of frequencies,
wherein said computer adjusts the RF power based on a shift in said plurality of reflection coefficients of the RF power over said spectrum of frequencies.

4. The apparatus of claim 1 wherein said RF probe includes an insulated antenna surrounded by a quartz sheath.

5. A plasma processing system comprising:
a chamber;
a workpiece holder in an interior of said chamber;
a first power circuit having a first power supply coupled to a first matching network, said first matching network coupled to a coil adjacent to said chamber;
a second power circuit having a second power supply coupled to a second matching network, said second matching network coupled to said workpiece holder; and
a feedback circuit including:
a Radio Frequency (RF) probe partially disposed in said interior of said chamber; and
a controller coupled to said RF probe and said first power circuit,
wherein said RF probe measures a change in plasma density in said interior of said chamber and said controller adjusts said first power supply in response to said change in plasma density.

6. The plasma processing system of claim 5 wherein said RF probe includes an insulated antenna surrounded by a quartz sheath.

7. The plasma processing system of claim 5 wherein said controller further comprises:
a network analyzer coupled to said RF probe; and
a computer coupled to said network analyzer and to said first power circuit.

8. The plasma processing system of claim 7 wherein said network analyzer includes a third power supply coupled to a high frequency (HF) transmitter and receiver.

9. The plasma processing system of claim 7 wherein said network analyzer generates a HF signal to said RF probe.

10. The plasma processing system of claim 9 wherein said network analyzer measures a plurality of reflection coefficients of said HF signal over a spectrum of frequencies, a change in said plurality of reflection coefficients of said absorbed HF signal representative of a change in plasma density.

11. A method for controlling the plasma density in a chamber of a plasma processing system comprising:
generating an RF signal in an interior of the chamber;
measuring a change in reflection coefficient of said RF signal over a spectrum of frequencies; and
adjusting a power supply configured to strike a plasma within the chamber in response to said change in reflection coefficient of said RF signal.

12. The method of claim 11 further comprising:
partially inserting a RF probe in a sidewall of the chamber; and
surrounding said RF probe with a quartz sheath, said RF probe generating said RF signal.

13. An apparatus for controlling the plasma density in a chamber of a plasma processing system comprising:
means for generating an RF signal in an interior of the chamber;
means for measuring a change in a reflection coefficient of said RF signal over a spectrum of frequencies; and
means for adjusting a power supply configured to strike a plasma within the chamber based on said change.

14. An apparatus for controlling the plasma density in a plasma processing system having a workpiece holder within a chamber, the apparatus comprising:
a power circuit arranged to supply RF power to the chamber suitable for striking a plasma within the chamber; and
a feedback circuit coupled to said power circuit, said feedback circuit including a RF probe partially disposed in an interior of the chamber, said RF probe measuring a change in plasma density, said feedback circuit adjusting RF power in response to said change in plasma density to maintain a near constant plasma density in the chamber.

15. A product prepared by a process comprising:
processing a wafer in a plasma chamber while maintaining plasma density at a near constant level in an interior of said plasma chamber;
wherein said maintaining includes:
generating an RF signal in said interior of said plasma chamber;
measuring a change in reflection coefficient of said RF signal over a spectrum of frequencies; and
adjusting a power supply configured to strike a plasma within said plasma chamber in response to said change in reflection coefficient of said RF signal.
